(19) United States
(12) Patent Application Publication
(10) Pub. No.: US 2002/0098712 A1
(43) Pub. Date: Jul. 25, 2002

(54) Multi-thickness oxide growth with in-situ scanned laser heating

(76) Inventors: Jaideep Mavoori, Richardson, TX (US); Douglas T. Grider, McKinney, TX (US); Sunil V. Hattangady, McKinney, TX (US); Douglas E. Mercer, Richardson, TX (US)

Correspondence Address: TEXAS INSTRUMENTS INCORPORATED, P O BOX 655474, M/S 3999, DALLAS, TX, 75265

(21) Appl. No.: 09/982,657

(22) Filed: Oct. 18, 2001

Related U.S. Application Data
(60) Provisional application No. 60/250,415, filed on Nov. 30, 2000.

(51) Int. Cl. H01L 21/31

(52) U.S. Cl. 438/771; 438/758

(57) ABSTRACT

Oxides of multiple thicknesses are made by selectively heating the wafer with a laser beam at the locations where enhanced oxide growth is desired.

### BACKGROUND AND SUMMARY OF THE INVENTION

The present invention relates to integrated circuit structures and fabrication methods, and more particularly to oxide growth.

Background

Various heating techniques have been used to assist chemical processes in integrated circuit fabrication. Furnace heating produces a generally uniform temperature throughout the volume of the wafer, whereas rapid thermal processing (RTP) processing techniques combine a vertical temperature gradient with a horizontally uniform temperature.

For advanced VLSI design and System On a Chip (SOC) technologies, there is a need for gate oxides of multiple thicknesses. Current solutions add processing steps like additional patterns, implantations, cleans, etc., making the manufactured product more expensive and in some cases even compromising the reliability of the gate dielectric.

Multi-Thickness Oxide Growth

The present application discloses an innovative process for growing films, preferably gate oxides, at multiple different levels without adding process steps.

In the preferred embodiment, this solution uses a single wafer chamber with the capability of heating the substrate selectively by means of a scanned laser beam. This laser beam heating is done in an oxidizing ambient (like O₂, N₂O, steam, etc.) and can be done in addition to a uniform substrate heating done by means of radiative/conductive heating. In the preferred embodiment, the laser beam is scanned on the wafer by a suitable driver mechanism. The scanning pattern corresponds to the patterns/areas on the die where increased oxidation is desired. By this selective scanning, the temperature of these portions of the wafer is increased hence enhancing the oxidation rate.

The solution can be extrapolated to other process scenarios where film thickness and other properties need to be varied selectively and where these properties are temperature dependent. Examples include deposition of silicates of varying thicknesses, selective activation of dopants, etc.

Advantages of the disclosed methods and structures, in various embodiments, can include one or more of the following:

cost effective alternative to other existing/known solutions, in terms of eliminating and not requiring additional process sequences;

offers fab cycle time advantages;

offers flexibility of growing varying thicknesses easily in a single process step;

solution can be extrapolated to even three or more oxide thicknesses if desired;

ability to grow oxides of multiple thicknesses in one step without any additional process steps.

### BRIEF DESCRIPTION OF THE DRAWINGS

The disclosed inventions will be described with reference to the accompanying drawings, which show important sample embodiments of the invention and which are incorporated in the specification hereof by reference, wherein:

FIG. 1 shows a process chamber implementing the preferred embodiment.

FIG. 2 is a flow chart showing key steps in the preferred embodiment.

### DETAILED DESCRIPTION OF THE PREFERRED EMBODIMENTS

The numerous innovative teachings of the present application will be described with particular reference to the presently preferred embodiment. However, it should be understood that this class of embodiments provides only a few examples of the many advantageous uses of the innovative teachings herein. In general, statements made in the specification of the present application do not necessarily delimit any of the various claimed inventions. Moreover, some statements may apply to some inventive features but not to others.

The preferred embodiment uses a chamber that has the ability to heat the wafer with a laser. The laser is used to heat the regions of the wafer where increased oxide growth is desired. This heating is selective, meaning that only the areas where thicker oxides are needed are heated by the laser, leaving non-exposed regions at a cooler temperature, and with therefore slower oxide growth. Because the oxide growth rate depends on the temperature of the substrate, this results in different thicknesses of oxide growth for the areas heated by the laser compared to those not heated by the laser.

The heating is done in a oxidizing ambient, for instance, 02, N₂O, or steam. In the preferred embodiment, the selective laser heating is done in addition to other means of substrate heating like basic radiative or conductive heating which will uniformly heat the wafer, such as rapid thermal processing.

The laser beam is scanned on the wafer by a suitable driver mechanism. The requirements for the scanning position accuracy are similar to those necessary in photolithography. The geometries for the purpose of the present invention would be several times larger than the critical dimensions of the gate, so no complex optical correction is required. Such laser scanning capability is well known in the art, and examples of such can be found in laser annealing systems and direct write systems.

The temperature in the region exposed to the laser radiation is increased with respect to the areas not exposed, creating a temperature differential and causing oxide growth rate to increase in the exact pattern desired. Thus, in the single process step where oxide is grown, this innovative concept allows multi-level oxides to be grown without added process steps. The thicknesses of the oxide in the differently illuminated (heated) regions depends on several factors, including duration of processing, intensity of the laser and the amount by which it increases the temperature of the wafer, and other oxide growth processing parameters.

Note that this technique need not necessarily be used in addition to standard rapid thermal processing (RTP). The use of patterned heating regions (be they created by lasers or other means) allows high temperature to be used where that high temperature is less likely to cause product defects. For instance, most device areas on the wafer would be harmed by too much temperature for several possible reasons (for example, too much diffusion of implanted ions). This innovative technique avoids such problems by not heating these sensitive regions to excessive temperatures. Other advantages of the present innovations will be mentioned below.

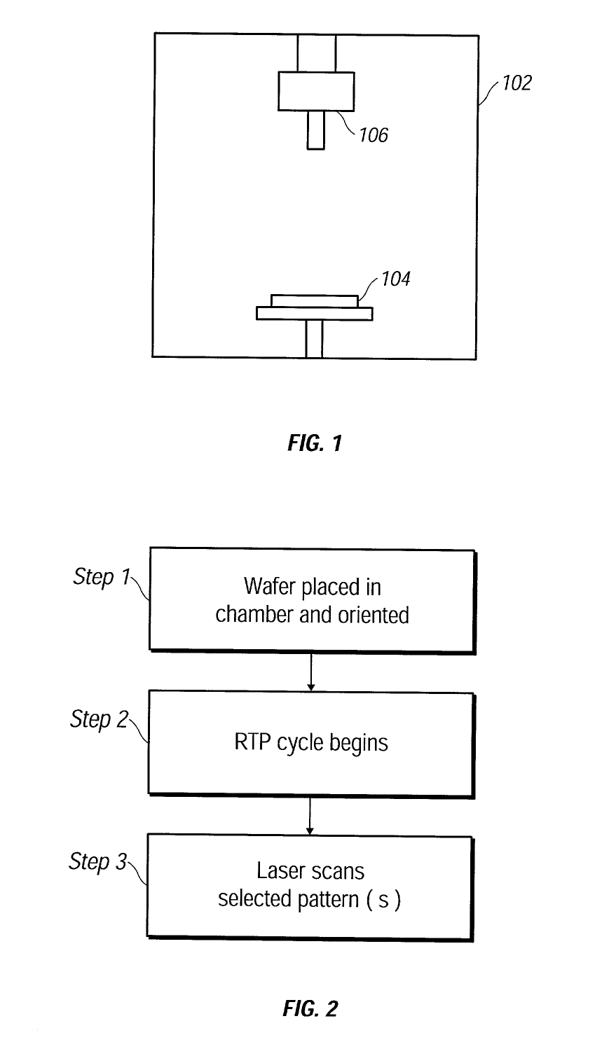

FIG. 1 shows a chamber equipped with the necessary laser scanner setup to practice the presently disclosed inventions. The chamber 102 houses a wafer 104 during processing. The surface of the wafer 104 is scanned with the laser 106, which scans the wafer surface selectively, controlled by a suitable driver mechanism (not shown). The scanning pattern corresponds to the areas on the die where increased oxidation is desired. The temperature of the scanned areas increases, causing accelerated oxide growth. The pattern data is used to control the laser driver. A typical spot size for a laser is on the order of a few microns and is smaller than the features of the areas being exposed. The laser raster is capable of steps sizes on the order of a few nanometers. Both raster scanning and vector scanning are contemplated by the present application.

The laser takes about one second to scan a die, depending on the desired temperature increase. The entire wafer can be scanned during the rapid thermal processing phase, where the entire wafer is heated. Oxide grows at its normal rate for the RTP temperature (e.g., 950 C.) while the regions heated by the laser grow at a faster rate according to the length of time the die is scanned (and thus the temperature).

In an example set of numbers, the process methodology comprised growing a base ISSG (In-Situ Steam Generated oxide) at 950 C. In this example, three different thicknesses of oxide are grown. The RTP phase lasts a total of 500 seconds, which corresponds to an oxide thickness of 16.2 angstroms. During that time, the laser selectively heats each die for one second each at a first pattern that corresponds to another thickness of oxide growth. In this example, the additional one second laser heating adds 10 angstroms to the oxide thickness (totaling 26.2 angstroms for that pattern). The laser also heats another patterned region of each die for 4 seconds, adding 29 angstroms to the oxide growth (totaling 45.2 angstroms for that region).

An ambient of N₂O and hydrogen were used in a typical RTP chamber modified to allow a scanned laser to selectively heat the wafer. The following table shows the results.

| | | Thickness | Sum |
|---|---|---|---|
| Temp Curve | Time [s] | [angstroms] | [angstroms] |
| 1050 C. | 1 | 10 | 26.2 |
| 950 C. | 500 | 16.2 | 16.2 |
| 1400 C. | 4 | 29.0 | 45.2 |
| | # scans | | |
| | feasible: 100 | | |

Since the whole wafer is heated to the base 950 C., and selected regions are heated to 1050 C. and 1400 C. respectively, three different thicknesses of oxide are obtained.

FIG. 2 shows a flow chart of the preferred process. The wafer is inserted into the process chamber for processing and the wafer is aligned (step 1). Next, the RTP cycle begins (step 2). During at least a portion of the RTP cycle, the laser illuminates the wafer surface according to the desired pattern (step 3). This exposure increases the temperature of the wafer at those locations and causes oxide growth to increase. After a given period of time, the oxide in the exposed regions will be thicker than the oxides of the non-exposed regions. Depending on the desired thicknesses, the laser can be used during only a part of the RTP process or throughout the RTP process.

The preferred embodiment uses a single wafer chamber with the capability of selectively scanning the laser on the wafer, similar to electron beam lithography setups.

Current typical solutions to the need for multiple thickness gate oxides add processing steps like additional patterns, implantations, cleans, etc. making the manufactured product more expensive and in some cases even compromising the reliability of the gate dielectric and device performance.

Advantages of the present application include the ability to grow a multi-level oxide in a single process step; elimination of added process sequences (such as implants, added patterns, etc.); fab cycle time advantages; this solution can be extrapolated to three or more oxide thicknesses if desired (making it compatible with multiple Vt implant schemes); this solution is extrapolatable to other process scenarios where a property needs to be varied at selective locations on the wafer surface and where that property is temperature dependent (for example, many CVD applications).

Modifications and Variations

As will be recognized by those skilled in the art, the innovative concepts described in the present application can be modified and varied over a tremendous range of applications, and accordingly the scope of patented subject matter is not limited by any of the specific exemplary teachings given, but is only defined by the issued claims.

These innovations are applicable to other process scenarios where film thickness (or another property) must be varied selectively and where the property to be varied is temperature dependent. Examples include deposition of silicates of varying thicknesses, and selective activation of dopants.

Electron beam lithography may also be adaptable to the present innovations. Though using an electron beam rather than a laser will necessarily mean some changes, the innovative concepts of this application are still applicable.

The patterning of the laser can be accomplished using other means, such as with a reticle and other optics to pattern the laser light to expose only the regions desired to be heated.

Though the preferred embodiment is described with reference to RTP processes, the innovations of the present application can be applied to any film growth situation where the growth can be selectively illuminated by a laser. RTP processing is not necessary for the practice of the present concepts.

Similarly, it will be readily recognized that the described process steps can also be embedded into hybrid process flows, such as BiCMOS or smart-power processes.

The teachings above are not necessarily strictly limited to silicon. In alternative embodiments, it is contemplated that these teachings can also be applied to structures and methods using other semiconductors, such as silicon/germanium and related alloys, gallium arsenide and related compounds and alloys, indium phosphide and related compounds, and other semiconductors, including layered heterogeneous structures.

It should also be noted that, over time, an increasing number of functions tend to be combined into a single chip. The disclosed inventions can still be advantageous even with different allocations of functions among chips, as long as the functional principles of operation described above are still observed.

Additional general background, which help to show the knowledge of those skilled in the art regarding variations and implementations of the disclosed inventions, may be found in the following documents, all of which are hereby incorporated by reference: Coburn, PLASMA ETCHING AND REACTIVE ION ETCHING (1982); HANDBOOK OF PLASMA PROCESSING TECHNOLOGY (ed. Rossnagel); PLASMA ETCHING (ed. Manos and Flamm 1989); PLASMA PROCESSING (ed. Dieleman et al. 1982); Schmitz, CVD OF TUNGSTEN AND TUNGSTEN SILICIDES FOR VLSI/ULSI APPLICATIONS (1992); METALLIZATION AND METAL-SEMICONDUCTOR INTERFACES (ed. Batra 1989); VLSI METALLIZATION: PHYSICS AND TECHNOLOGIES (ed. Shenai 1991); Murarka, METALLIZATION THEORY AND PRACTICE FOR VLSI AND ULSI (1993); HANDBOOK OF MULTILEVEL METALLIZATION FOR INTEGRATED CIRCUITS (ed. Wilson et al. 1993); Rao, MULTILEVEL INTERCONNECT TECHNOLOGY (1993); CHEMICAL VAPOR DEPOSITION (ed. M. L. Hitchman 1993); and the semiannual conference proceedings of the Electrochemical Society on plasma processing.

What is claimed is:

1. A method of integrated circuit fabrication, comprising the steps of:
varying the temperature of selected locations of a wafer with a laser to thereby induce different rates of chemical reaction at different locations on said wafer.

2. The method of claim 1, wherein said chemical reaction is oxide growth.

3. The method of claim 1, wherein said chemical reaction is the selective activation of dopants.

4. The method of claim 1, wherein some of said selected locations are heated to higher temperature than others of said selected locations.

5. A method of integrated circuit fabrication, comprising the steps of:
heating a wafer in a process chamber;
heating selected locations of said wafer with a laser, to cause a difference in temperature between said selected locations and the rest of said wafer, to thereby vary a temperature dependent property.

6. The method of claim 5, wherein said temperature dependent property is the growth rate of an oxide at the surface of said wafer.

7. The method of claim 5, wherein some of said selected locations are heated with said laser for longer periods than others of said selected locations.

8. The method of claim 5, wherein said temperature dependent property is the growth of a film.

9. The method of claim 5, wherein said heating of said selected locations occurs during a single process phase.

10. A method of integrated circuit fabrication, comprising the steps of:
heating selected areas of the surface of a wafer during a process phase, said selected areas being heated to a higher temperature than the rest of the wafer surface;
growing a film on said surface;
wherein said film grows faster in said selected areas than outside said selected areas.

11. The method of claim 10, wherein said film is an oxide.

12. The method of claim 10, wherein some of said selected areas are heated more than others of said selected locations.

13. The method of claim 10, wherein said selected areas are heated by a laser.

14. The method of claim 10, wherein said steps of heating and growing occur during a single process phase.

15. An integrated circuit fabrication chamber, comprising:
a stand for a wafer;
a laser positioned to selectively illuminate the surface of said wafer;
wherein said laser varies the temperature of selected locations of said wafer to thereby induce different rates of chemical reaction at different locations on said wafer.

16. The chamber of claim 15, wherein said chemical reaction is oxide growth.

17. The method of claim 15, wherein said chemical reaction is the selective activation of dopants.

18. The method of claim 15, wherein some of said selected locations are heated to higher temperature than others of said selected locations.
